(19) United States
(12) Patent Application Publication
(10) Pub. No.: US 2006/0045214 A1
(43) Pub. Date: Mar. 2, 2006

(54) Receiving method and apparatus for variable rate

(75) Inventor: Sanshiro Shiina, Mizuho-City (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD

(21) Appl. No.: 11/214,000

(22) Filed: Aug. 30, 2005

(30) Foreign Application Priority Data
Aug. 31, 2004 (JP) 2004-253492

(51) Int. Cl. H03D 1/00

(52) U.S. Cl. 375/341

(57) ABSTRACT

When the transmission rate is 200 Mbps or lower, a switching unit outputs a signal to a first processing unit. When the transmission rate exceeds 200 Mbps, the switching unit outputs a signal to a second processing unit. When the transmission rate acquired in a header decoder is 200 Mbps or lower, the first processing unit subjects an input signal to hard decision and decodes the signal subjected to hard decision. When the transmission rate acquired in the header decoder exceeds 200 Mbps, the second processing unit subjects an input signal to soft decision and decodes the signal subjected to soft decision.

### BACKGROUND OF THE INVENTION

1. Field of the Invention

The present invention relates to a receiving technology and, more particularly, to a receiving method and apparatus capable of receiving a signal which is set at a variable transmission rate and which is coded according to a predetermined scheme.

2. Description of the Related Art

In wireless communication, error correction technology is commonly employed in order to improve the signal transmission quality. Error correction technology is comprised of coding technology and decoding technology. A transmitter apparatus codes information to be transmitted and a receiver apparatus decodes a received signal. Convolution coding is one of error correction technologies that provide excellent error correction capabilities. The decoding technology corresponding to convolution coding is Viterbi decoding. Normally, Viterbi decoding is performed on a signal subjected to hard decision. However, it may be performed on a signal subjected to soft decision in order to improve the characteristic of Viterbi decoding. Related art discloses switching from soft-decision-based Viterbi decoding to hard-decision-based Viterbi decoding provided that the transmission channel is in proper condition, for the purpose of reducing power consumption required in soft-decision-based Viterbi decoding.

Related Art List

(1) Japanese Patent Application Laid-Open No. 2000-269825.

In the field of wireless communication, study has been conducted on the use of spread spectrum (SS) communication scheme. The spread spectrum communication scheme encompasses a direct sequence (DS) scheme and a frequency hopping (FH) scheme. In the FH scheme, spread spectrum communication is performed by hopping between carrier frequencies in accordance with a series of codes. The spectrum according to FH occupies a wide frequency band under a long-term observation. However, a bit or a symbol under observation reveals itself as a signal of a narrower band than a DS signal, occupying only a specific frequency band. It is due to this aspect that the FH scheme is called an SS system adapted for avoidance of interference. The FH scheme as such is advantageous in that the probability of a plurality of users communicating in the same frequency at the same time is reduced.

One of the technologies to improve the signal transmission rate is orthogonal frequency division multiplexing (OFDM), which is known as one of multi-carrier transmission schemes. There is further proposed MB-OFDM in which the FH scheme and the OFDM scheme are combined. MB-OFDM is applied to wireless personal area network (WPAN). A WPAN is a wireless network adapted for a distance range narrower than that covered by wireless LAN and is a short-range wireless network for PDAs and peripherals. A band between 3.1 GHz and 10.6 GHz is scheduled to be used in ultra wide band (UWB) in which the MB-OFDM scheme is used.

The MB-OFDM scheme applied to WPAN supports a plurality of data transmission rates. That is, a plurality of coding rates are defined in the error correction scheme. Generally, error resilience of a signal differs in a case of low data transmission rate and in a case of high data transmission rate. As a result, the transmission quality is degraded if hard-decision-based Viterbi decoding is used when error resilience is poor. In contrast, the transmission quality is not degraded if soft-decision-based Viterbi decoding is used when error resilience is high. However, power consumption is increased as compared to a case where hard-decision-based Viterbi decoding is used. Accordingly, requirement for Viterbi decoding changes as the data transmission rate changes.

### SUMMARY OF THE INVENTION

We have made the invention with the aforementioned background in mind. The invention provides a receiving method and apparatus adapted to variable transmission rates and capable of reducing power consumption while maintaining predetermined transmission quality.

In an embodiment of the present invention, a receiver apparatus may comprise: an input unit fed with a received signal which is set at a variable transmission rate and which is coded; an acquiring unit which acquires a transmission rate for the received signal fed to the input unit; a hard-decision-based decoder unit which subjects the received signal to hard decision when the transmission rate acquired in the acquiring unit is of a threshold value or lower, and which decodes the received signal subjected to hard decision; and a soft-decision-based decoder unit which subjects the received signal to soft decision when the transmission rate acquired in the acquiring unit exceeds the threshold value, and which decodes the received signal subjected to soft decision.

The “transmission rate” may be configured to be of various values in accordance with the coding rate. Factors other than the coding rate may determine the transmission rate. For example, the modulation scheme may determine the transmission rate.

When the transmission rate is low, the transmission quality tends to be high. The embodiment addresses this by using hard decision so as to reduce power consumption. When the transmission rate is high, the transmission quality tends to be low. This is addressed by using soft decision so as to improve the transmission quality.

The received signal may be of a format in which the same code is repeated according to a predetermined rule when the transmission rate for the received signal fed to the input unit is of a threshold value or lower, and the receiver apparatus may further comprise a synthesis unit which synthesizes the received signal such that the same codes are matched according to the rule and which outputs the synthesized received signal to the hard-decision-based decoder unit.

The term “format in which the same code is repeated” may refer to a repetition of time-domain signals or frequency-domain signals.

Since diversity effect is achieved by synthesizing signals, degradation in transmission quality is prevented even when hard decision is employed.

The soft-decision-based decoder unit may adjust the number of bits used in soft decision of the received signal in accordance with the transmission rate acquired. Since the transmission quality differs depending on the transmission rate, improvement in transmission quality and reduction in power consumption are achieved by adjusting the number of bits.

The received signal fed to the input unit may be interleaved, and the receiver apparatus may further comprise a deinterleaver unit which deinterleaves, when the hard-decision-based decoder unit is operated, the received signal subjected to hard decision and causes the hard-decision-based decoder unit to decode the deinterleaved received signal, or which deinterleaves, when the soft-decision-based decoder is operated, the received signal subjected to soft decision and causes the soft-decision-based decoder unit to decode the deinterleaved received signal. By performing deinterleaving, burst signal errors are distributed and converted into random signal errors. With this, the transmission quality is improved.

The hard-decision-based decoder unit and the soft-decision-based decoder unit may be implemented as a single circuit, and, in accordance with whether the hard-decision-based decoder unit or the soft-decision-decoder unit is operated, the number of bits used in a decoding process may be switched in the circuit. By sharing the decoder unit as a single circuit, the circuit scale is reduced.

Another aspect of the present invention relates to a receiving method. The receiving method decodes a received signal which is set at a variable transmission rate and which is coded, the decoding being performed such that, when the transmission rate for the received signal is of a threshold value or lower, the received signal is subject to hard decision before being decoded, and, when the transmission rate exceeds the threshold value, the received signal is subject to soft decision before being decoded.

Arbitrary combinations of the aforementioned constituting elements, and implementations of the invention in the form of methods, apparatuses, systems, recording mediums and computer programs may also be practiced as additional modes of the present invention.

According to the present invention, predetermined quality of transmission is maintained and power consumption is reduced in a situation where the transmission rate is variably set.

Moreover, this summary of the invention does not necessarily describe all necessary features so that the invention may also be sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 illustrates the structure of a communication system according to an example of the present invention.

FIG. 2 is a chart illustrating the allocation of hopping frequencies in the communication system of FIG. 1.

FIGS. 3A through 3B illustrate the structure of burst format of the communication system of FIG. 1.

FIG. 4 is a table listing parameter values for each transmission rate in the communication system of FIG. 1.

FIG. 5 illustrates the structure of a demodulating unit of FIG. 1.

FIG. 6 is a flowchart illustrating the procedure of reception in the receiver apparatus of FIG. 1.

FIG. 7 illustrates a relationship between the transmission rates and the number of bits in the soft decision unit of FIG. 5.

FIG. 8 illustrates an alternative structure of the demodulating unit of FIG. 1.

FIG. 9 illustrates another alternative structure of the demodulating unit of FIG. 1.

### DETAILED DESCRIPTION OF THE INVENTION

The invention will now be described based on the following embodiments which do not intend to limit the scope of the present invention but exemplify the invention. All of the features and the combinations thereof described in the embodiments are not necessarily essential to the invention.

A summary will be given before describing the present invention in specific detail. An example of the present invention relates to a receiver apparatus receiving a burst signal. Data included in a burst signal received by the receiver apparatus is convolution coded. A plurality of transmission rates are defined for data by changing the coding rate. At the head of the burst signal is included a header signal containing control information.

The header signal contains information about the data transmission rate. The transmission rate of the header signal is predefined.

The receiver apparatus according to the example is provided with a soft-decision-based Viterbi decoder (hereinafter, referred to as soft-decision Viterbi decoder) and a hard-decision-based Viterbi decoder (hereinafter, referred to as a hard-decision Viterbi decoder). Upon receipt of a burst signal, the receiver apparatus retrieves information related to the transmission rate included in the header signal. When the transmission rate is of a threshold value or lower, the receiver apparatus operates the hard-decision Viterbi decoder so as to process the received burst signal. When the transmission rate exceeds the threshold value, the receiver apparatus operates the soft-decision Viterbi decoder to process the received burst signal. When the transmission rate is low, the transmission quality tends to be high. Therefore, the transmission quality is degraded only slightly if a hard-decision-based decoding process is performed. When the transmission rate is high, the transmission quality tends to low. This is addressed by performing a soft-decision-based decoding process so as to improve the transmission quality. The following example is directed to the MB-OFDM scheme in which the OFDM scheme and the FH scheme are combined.

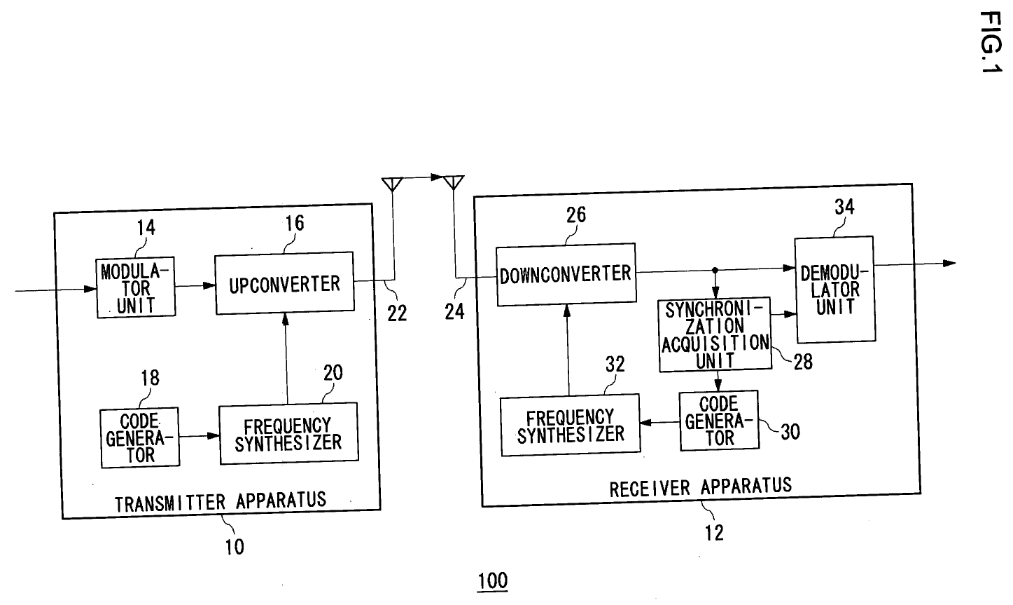

FIG. 1 illustrates the structure of a communication system 100 according to the example. The communication system 100 includes a transmitter apparatus 10 and a receiver apparatus 12.

The transmitter apparatus 10 includes a modulator unit 14, an upconverter 16, a code generator unit 18, a frequency synthesizer 20 and a transmission antenna 22. The receiver apparatus 12 includes a reception antenna 24, a downconverter 26, a synchronization acquisition unit 28, a code generator unit 30, a frequency synthesizer 32 and a demodulator unit 34.

The modulator 14 modulates a data signal according to the OFDM modulation scheme. The modulator 14 also performs 25 convolution coding with variably set coding rates. The data signal has the format of a burst signal. The code generator unit 18 generates pseudo random code signals. The frequency synthesizer 20 generates randomly hopped group of carriers by referring to the pseudo random code signals. The upconverter 16 subjects the modulated signal to frequency hopping by using the randomly hopped group of carriers. The transmission antenna 22 transmits the frequency-hopped signal. The receiver antenna 24 receives the signal transmitted from the transmission antenna 22.

Like the frequency synthesizer 20, the frequency synthesizer 32 generates randomly hopped group of carriers. The downconverter 26 subjects the received signal to frequency conversion by using the randomly hopped group of carriers.

When the carrier frequency hopping pattern generated by the frequency synthesizer 20 matches the carrier frequency hopping pattern generated by the frequency synthesizer 32, the downconverter 26 is capable of subjecting the received signal to accurate frequency conversion. When they do not match, accurate frequency conversion is not possible. The synchronization acquisition unit 28 synchronizes the carrier frequency hopping pattern generated by the frequency synthesizer 32 with the frequency hopping pattern of the received signal, in order to subject the received signal to accurate frequency conversion. The synchronization acquisition unit 28 also performs synchronization of the symbol timing of the received signal and controls the demodulator unit 34. The demodulator 34 performs a process corresponding to the modulator 14.

The structure as described above may be implemented by hardware including a CPU, a memory and an LSI of an arbitrary computer and by software including a program provided with reservation and management functions loaded into the memory. FIG. 1 depicts functional blocks implemented by cooperation of the hardware and software. Therefore, it will be obvious to those skilled in the art that the functional blocks may be implemented by a variety of manners including hardware only, software only or a combination of both.

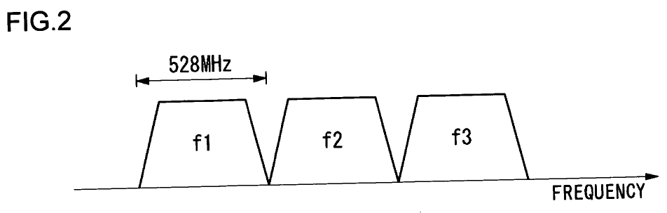

FIG. 2 is a chart illustrating the allocation of hopping frequencies in the MB-OFDM scheme. As illustrated, a frequency channel (for example “f1”) has a bandwidth of 528 MHz. Three frequency channels each having the same bandwidth are provided.

In the communication system 100; a channel is selected from “f1” through “f3” in accordance with a predetermined hopping pattern so that communication proceeds in the selected frequency channel.

The communication system 100 hops from one frequency to another in units of symbols. For example, the communication system switches between frequency channels “f1”, “f2” and “f₃” in the stated after each symbol. A symbol interval in the MB-OFDM scheme is defined as a unit which contains an interval defined by the fast Fourier transform (FFT) size (number of points) and a guard interval etc.

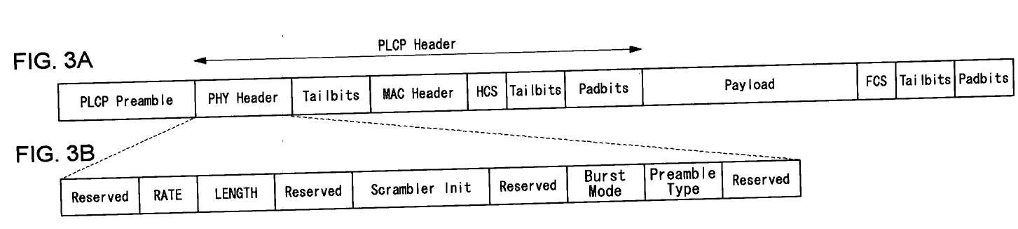

FIGS. 3A through 3B illustrate the structure of burst format. FIG. 3A illustrates the burst format in the MB-OFDM scheme. The format comprises “PLCP Preamble”, “PLCP Header” and “Payload” in the stated order. “PLCP Preamble” corresponds to a training signal used in timing synchronization. “PLCP Header” corresponds to a control signal. “Payload” corresponds to a data signal. Each of blocks is comprised of a predetermined number of symbols. The transmission rate for “PLCP Preamble” and “PLCP Header” is defined to be 53.3 Mbps or 55 Mbps. The transmission rate for “Payload” is set to be variable.

FIG. 3B illustrates the format of “PLCP header”. The format comprises “Reserved”, “RATE”, “LENGTH”, “Reserved”, “Scrambler Init”, “Reserved”, “Burst mode”, “Preamble Type” and “Reserved” in the stated order. “Rate” indicates the transmission rate of “Payload”. “LENGTH” indicates the data size of “Payload”. “Scrambler Init” indicates an initial value of a scrambler. The receiver apparatus 12 of FIG. 1 refers to “RATE” in “PLCP Header” so as to know the transmission rate of “Payload”.

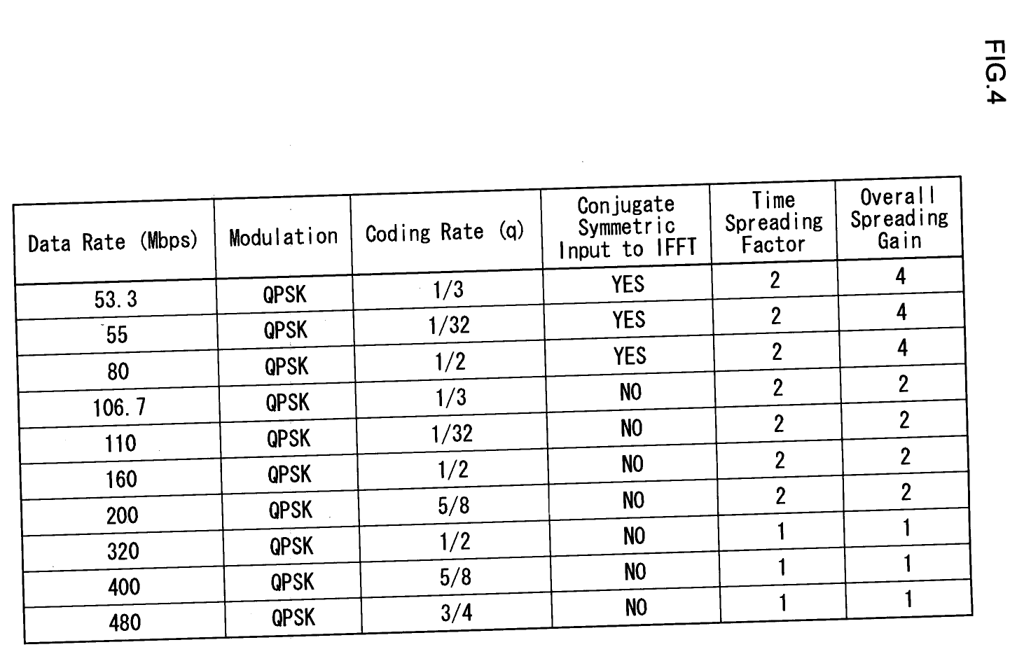

FIG. 4 is a table listing parameter values for each transmission rate. This table corresponds to the MB-OFDM scheme. “Data Rate” corresponds to the transmission rate expressed in Mbps. “QPSK” is set in “Modulation” without exception. The transmission rate is determined in accordance with the setting in “Coding rate”, “Conjugate Symmetric Input to IFFT”, “Time Spreading Factor”.

“Time Spreading Factor” indicates the number of times that the same symbol is transmitted. That is, if “1” is set in “Time Spreading Factor”, a given symbol is transmitted only once. If “2” is set in “Time Spreading Factor”, a given symbol is transmitted twice carrying the same values. This reduces the transmission efficiency to half. However, the transmission quality is improved since this requires that only one of the same symbols transmitted in two occasions is properly received. This corresponds to time diversity. As mentioned before, the MB-OFDM scheme hops from one frequency to another after each symbol. Therefore, the same symbols are transmitted in different frequency channels. This corresponds to frequency diversity. That is, sub-band diversity as described above is performed.

When “YES” is set in “Conjugate Symmetric Input to IFFT”, a data signal is inserted twice in the same symbol. In this case, the same data are allocated to different sub-carriers so that the frequency diversity effect is achieved.

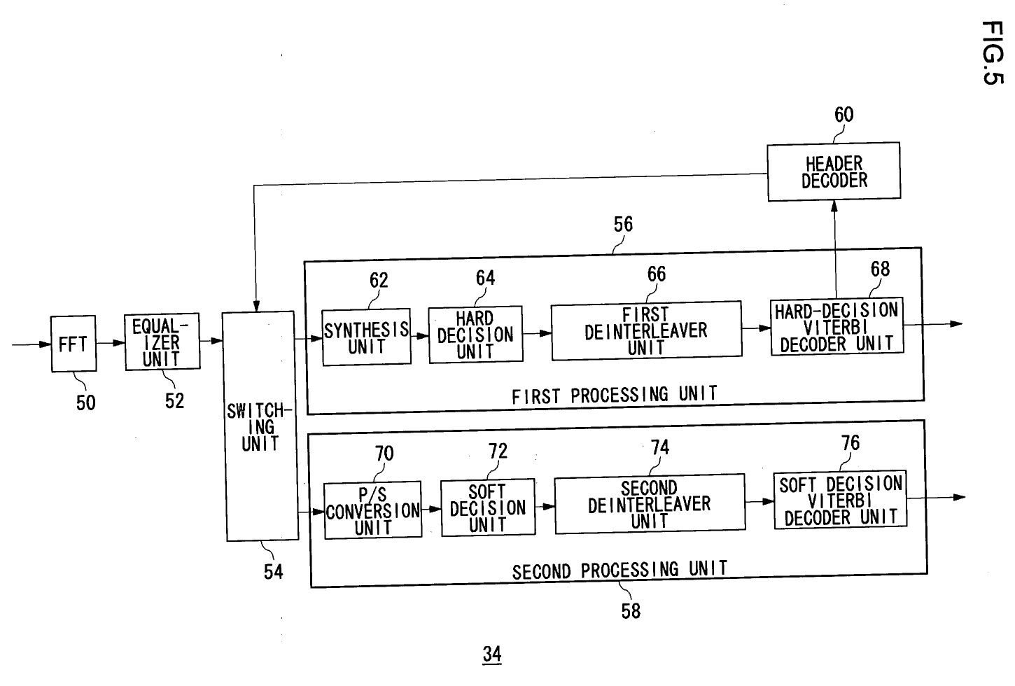

FIG. 5 illustrates the structure of the demodulator unit 34. The demodulator unit 34 includes an FFT 50, an equalization unit 52, a switching unit 54, a first processing unit 56, a second processing unit 58 and a header decoder 60. The first processing unit 56 includes a synthesis unit 62, a hard decision unit 64, a first deinterleaver unit 66 and a hard decision Viterbi decoder unit 68. The second processing unit 58 includes a P/S conversion unit 70, a soft decision unit 72, a second deinterleaver unit 74 and a soft decision Viterbi decoder unit 76.

The FFT 50 subjects an input signal to fast Fourier transform so as to convert a time-domain signal into a frequency-domain signal. As illustrated in FIG. 4, the transmission rate of the input signal is configured to be variable. When the transmission rate is 200 Mbps or lower, the signal is of a format in which the same code is repeated at the transmitting end according to a predetermined rule. The predetermined rule is such that consecutive, repeated symbols have the same value. Further, the signal is interleaved.

The equalizer unit 52 estimates the characteristics of the transmission channel of the received signal and equalizes the received signal by referring to the estimated transmission channel characteristics. Since the received signal is transformed into the frequency domain by the FFT 50, the equalizer unit 52 performs equalization on the frequency-domain signal. Channel estimation is performed in a period indicated by “PLCP Preamble” of FIG. 3A.

The switching unit 54 outputs the signal input from the equalizer unit 52 to the first processing unit 56 or the second processing unit 58. The switching unit 54 outputs the input signal from the equalizer unit 52 to the first processing unit 56 in a period of “PLCP Header” of FIG. 3A. The first processing unit 56 then subjects the signal to a process described later. The header decoder 60 acquires the transmission rate for “Payload” by referring to “RATE” of FIG. 3B included in the signal processed in the first processing unit 56. The transmission rate acquired by the header decoder 60 is reported to the switching unit 54.

The switching unit 54 outputs the signal to the first processing unit 56 over a period of “Payload” of FIG. 3A if the transmission rate is “200 Mbps” or lower. If the transmission rate exceeds “200 Mbps”, the switching unit 54 outputs the signal to the second processing unit 58. In the above process, it can be said that the switching unit 54 sets the threshold value to “200 Mbps”.

If the transmission rate acquired by the header decoder 60 is 200 Mbps or lower, the first processing unit 56 subjects the input signal to hard decision and decodes the signal subjected to hard decision. The synthesis unit 62 synthesizes the input signal by establishing correspondence between matching codes according to a rule requiring that consecutive, repeated symbols have the same value.

The hard decision unit 64 subjects the input signal from the synthesizer unit 62 to hard decision and outputs a signal with a value “1” or a value “0”. The first deinterleaver unit 66 deinterleaves the signal subjected to hard decision by the hard decision unit 64. The rule for deinterleaving is predetermined so as to correspond to the rule in the interleaver unit (not shown) included in the transmitter apparatus 10 of FIG. 1.

The hard decision Viterbi decoder unit 68 performs hard-decision Viterbi decoding on the signal deinterleaved by the first deinterleaver unit 66. Since hard-decision Viterbi decoding is performed according to the related art, the description thereof is omitted. Hard-decision Viterbi decoding is achieved by computation of branch metrics, computation of survival paths and comparison. The process in the hard-decision Viterbi decoder unit 68 is changed in accordance with the coding rate.

If the transmission rate acquired in the header decoder 60 is greater than 200 Mbps, the second processing unit 58 subjects the input signal to soft decision and decodes the signal subjected to soft decision. The P/S conversion unit 70 subjects the signal to parallel/serial conversion. The soft decision unit 72 subjects the input signal from the P/S conversion unit 70 to soft decision and outputs a signal of a value represented by several bits. The second deinterleaver unit 74 deinterleaves the signal subjected to soft decision by the soft decision unit 72.

The soft-decision Viterbi decoder unit 76 performs soft-decision Viterbi decoding on the signal deinterleaved by the second deinterleaver unit 74. Since soft-decision Viterbi decoding is performed according to the related art, the description thereof is omitted. Like hard-decision Viterbi decoding, soft-decision Viterbi decoding is achieved by computation of branch metrics, computation of survival paths, comparison, etc. While the hard-decision Viterbi decoder unit 68 computes branch metrics by measuring Hamming distance, the soft-decision Viterbi decoder unit 76 computes branch metrics by measuring square Euclidean distance. The process in the soft-decision Viterbi decoder unit 76 is changed in accordance with the coding rate.

The supply of clocks to one of the first processing unit 56 and the second processing unit 58 not selected is suspended. With this, power consumption is prevented from increasing even with a structure where two circuits, namely, the first processing unit 56 and the second processing unit 58, are provided for decoding.

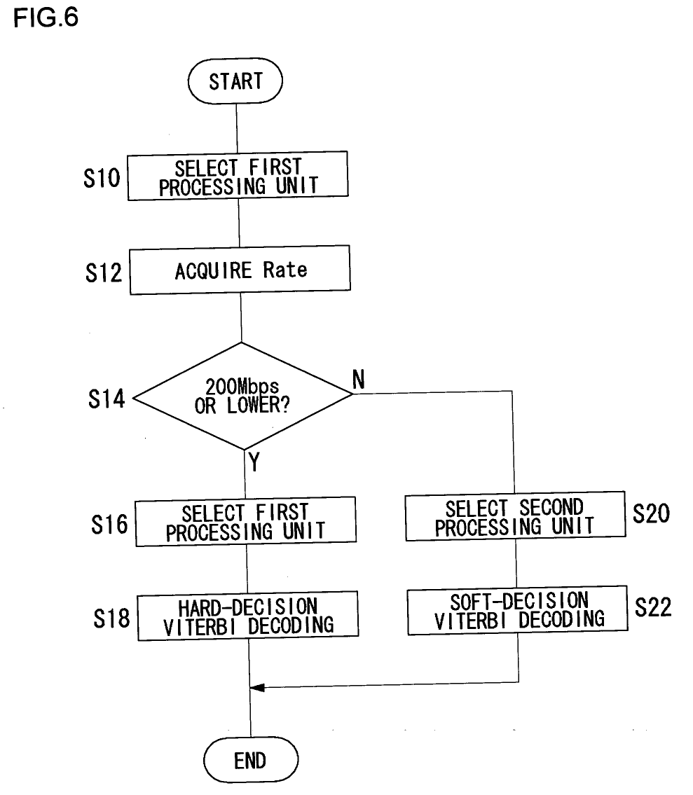

A description will be given of the operation of the receiver apparatus 12 described above. FIG. 6 is a flowchart illustrating the procedure of reception operation in the receiver apparatus 12. The switching unit 54 selects the first processing unit 56 in a period of “PLCP Header” (S10). After the first processing unit 56 performs hard-decision-based Viterbi decoding, the header decoder 60 acquires “RATE” included in “PLCP Header” (S12). When the transmission rate is “200 Mbps” or lower (Y in S14), the switching unit 54 selects the first processing unit 56 (S16). The first processing unit 56 performs hard-decision-based Viterbi decoding (Sl8). When the transmission rate is not “200 Mbps” or lower (N in S14), the switching unit 54 selects the second processing unit 58 (S20). The second processing unit 58 performs soft-decision-based Viterbi decoding (S22).

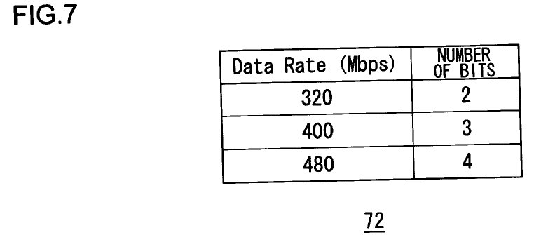

A description will be given of a variation of the demodulation unit 34 according to the example described above. The soft-decision unit 72 of FIG. 5 subjects the input signal from the P/S conversion unit 70 to soft decision using a plurality of bits. In this variation, the soft decision unit 72 adjusts the number of bits used in soft decision on the input signal from the P/S conversion unit 70, in accordance with the transmission rate acquired. FIG. 7 illustrates a relationship between transmission rates and the number of bits in the soft decision unit 72. When the transmission rate is “320 Mbps”, the number of bits is “2”. When the transmission rate is “400 Mbps”, the number of bits is “3”. When the transmission rate is “480 Mbps”, the number of bits is “4”. Generally, as the transmission rate is increased, the transmission quality tends to be degraded. In contrast, as the number of bits in soft decision is increased, the transmission quality tends to be improved. Therefore, degradation in transmission quality due to an increase in transmission rate is compensated by increasing the number of bits in soft decision when the transmission rate is increased. To achieve the operation described above, a signal line (not shown) connects the header decoder 60 to the soft decision unit 72.

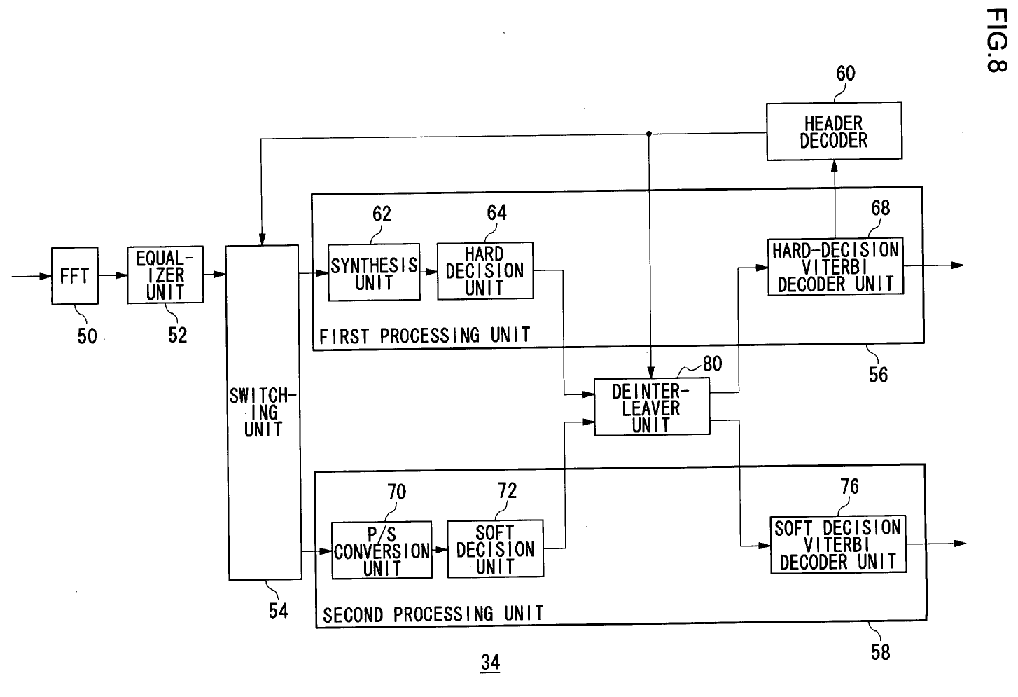

FIG. 8 illustrates an alternative structure of the demodulator unit 34. The demodulator 34 of FIG. 8 differs from the demodulator 34 of FIG. 5 in that the deinterleaver unit 80 is shared. The synthesis unit 62, the hard decision unit 64, the hard-decision-based Viterbi decoder unit 68 in the first processing unit 56 perform the same processes as described already. Also, the P/S conversion unit 70, the soft decision unit 72 and the soft-decision-based Viterbi decoder unit 76 of the second processing unit 58 perform the same processes as described. However, the deinterleaver unit 80 is commonly used for processes in the first processing unit 56 and in the second processing unit 58.

For this purpose, the deinterleaver unit 80 is connected to the header decoder 60 and acquires information on transmission rate from the header decoder 60. When hard decision is performed, i.e., when the switching unit 54 selects the first processing unit 56, the deinterleaver unit 80 performs deinterleaving corresponding to the signal subjected to hard decision. When soft decision is performed, i.e., when the switching unit 54 selects the second processing unit 58, the deinterleaver unit 80 performs deinterleaving corresponding to the signal subjected to soft decision. As compared with the structure of FIG. 5, the circuit scale of FIG. 8 is reduced since the deinterleaver unit 80 is shared.

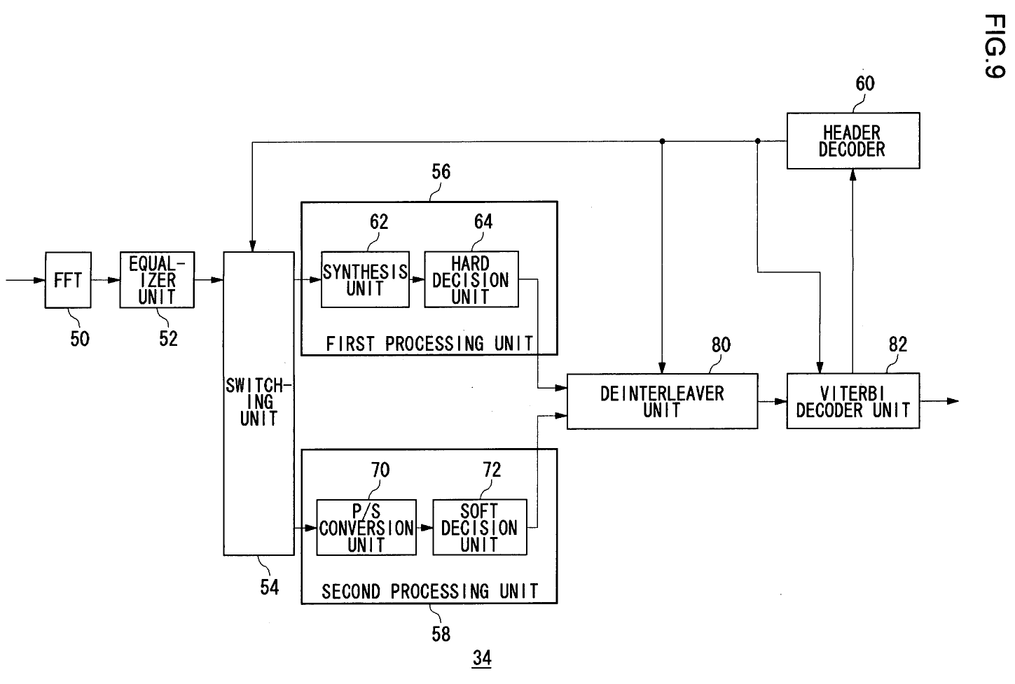

FIG. 9 illustrates another alternative structure of the demodulator unit 34. Similarly to the demodulator unit 34 of FIG. 8, the deinterleaver unit 80 is shared. Further, the hard-decision-based Viterbi decoder unit 68 and the soft-decision-based Viterbi decoder unit 76 are implemented as a single Viterbi decoder unit 82. In accordance with the selection by the switching unit 54 of the first processing unit 56 or the second processing unit 58, the number of bits used in a decoding process is switched in the circuit.

When hard decision is performed, i.e., when the switching unit 54 selects the first processing unit 56, the Viterbi decoder unit 82 performs Viterbi decoding corresponding to a signal subjected to hard decision. When soft decision is performed, i.e., when the switching unit 54 selects the second processing unit 58, the Viterbi decoder unit 82 performs Viterbi decoding corresponding to a signal subjected to soft decision. As mentioned before, the method of deriving branch metrics in the Viterbi decoder unit 82 differs in hard decision and in soft decision. The Viterbi decoder unit 82 is adapted for both. In the structure of FIG. 9, the Viterbi decoder unit 82 is shared so that the circuit scale is further reduced.

When the transmission rate is low, the transmission quality tends to be high. In this case, the example of the present invention achieves reduction in power consumption by using hard decision. When the transmission rate is high, the transmission quality tends to be low. In this case, the transmission quality is improved by using soft decision. By combining the above processes, reduction in power consumption and improvement in transmission quality are achieved in accordance with the transmission rate. Since diversity effect is achieved by synthesizing signals, degradation in transmission quality is prevented even when hard decision is employed. Since the transmission quality varies with the transmission rate, improvement in transmission quality and reduction in power consumption are achieved by adjusting the number of bits used in soft decision. By performing deinterleaving, burst signal errors are distributed and converted into random signal errors. Therefore, the transmission quality is improved. By allowing a circuit for decoding to be shared, the circuit scale is reduced.

Described above is an explanation based on the examples. The embodiment is only illustrative in nature and it will be obvious to those skilled in the art that variations in constituting elements and processes are possible within the scope of the present invention.

In the example of the present invention, convolution coding is employed as a coding scheme. In association with this, the demodulator unit 34 performs Viterbi decoding. Alternatively, combinations other than convolution coding and Viterbi decoding may be employed. According to this variation, the present invention is applicable to various error correction technologies. What is essential is that a decoding technology capable of soft-decision-based decoding and hard-decision-based decoding is available for use.

While the preferred embodiments of the present invention have been described using specific terms, such description is for illustrative purposes only, and it is to be understood that changes and variations may be made without departing from the spirit or scope of the appended claims.

What is claimed is:

1. A receiver apparatus comprising:
an input unit fed with a received signal which is set at a variable transmission rate and which is coded;
an acquiring unit which acquires a transmission rate for the received signal fed to the input unit;
a hard-decision-based decoder unit which subjects the received signal to hard decision when the transmission rate acquired in the acquiring unit is of a threshold value or lower, and which decodes the received signal subjected to hard decision; and
a soft-decision-based decoder unit which subjects the received signal to soft decision when the transmission rate acquired in the acquiring unit exceeds the threshold value, and which decodes the received signal subjected to soft decision.

2. The receiver apparatus according to claim 1, wherein the received signal is of a format in which the same code is repeated according to a predetermined rule when the transmission rate for the received signal fed to the input unit is of a threshold value or lower, and wherein the receiver apparatus further comprises a synthesis unit which synthesizes the received signal such that the same codes are matched according to the rule and which outputs the synthesized received signal to the hard-decision-based decoder unit.

3. The receiver apparatus according to claim 1, wherein the soft-decision-based decoder unit adjusts the number of bits used in soft decision of the received signal in accordance with the transmission rate acquired.

4. The receiver apparatus according to claim 1, wherein the received signal fed to the input unit is interleaved, and wherein the receiver apparatus further comprises a deinterleaver unit which deinterleaves, when the hard-decision-based decoder unit is operated, the received signal subjected to hard decision and causes the hard-decision-based decoder unit to decode the deinterleaved received signal, or which deinterleaves, when the soft-decision-based decoder is operated, the received signal subjected to soft decision and causes the soft-decision-based decoder unit to decode the deinterleaved received signal.

5. The receiver apparatus according to claim 2, wherein the received signal fed to the input unit is interleaved, and wherein the receiver apparatus further comprises a deinterleaver unit which deinterleaves, when the hard-decision-based decoder unit is operated, the received signal subjected to hard decision and causes the hard-decision-based decoder unit to decode the deinterleaved received signal, or which deinterleaves, when the soft-decision-based decoder is operated, the received signal subjected to soft decision and causes the soft-decision-based decoder unit to decode the deinterleaved received signal.

6. The receiver apparatus according to claim 3, wherein the received signal fed to the input unit is interleaved, and wherein the receiver apparatus further comprises a deinterleaver unit which deinterleaves, when the hard-decision-based decoder unit is operated, the received signal subjected to hard decision and causes the hard-decision-based decoder unit to decode the deinterleaved received signal, or which deinterleaves, when the soft-decision-based decoder is operated, the received signal subjected to soft decision and causes the soft-decision-based decoder unit to decode the deinterleaved received signal.

7. The receiver apparatus according to claim 1, wherein the hard-decision-based decoder unit and the soft-decision-based decoder unit are implemented as a single circuit, and wherein, in accordance with whether the hard-decision-based decoder unit or the soft-decision-decoder unit is operated, the number of bits used in a decoding process is switched in the circuit.

8. The receiver apparatus according to claim 2, wherein the hard-decision-based decoder unit and the soft-decision-based decoder unit are implemented as a single circuit, and wherein in accordance with whether the hard-decision-based decoder unit or the soft-decision-decoder unit is operated, the number of bits used in a decoding process is switched in the circuit.

9. The receiver apparatus according to claim 3, wherein the hard-decision-based decoder unit and the soft-decision-based decoder unit are implemented as a single circuit, and wherein in accordance with whether the hard-decision-based decoder unit or the soft-decision-decoder unit is operated, the number of bits used in a decoding process is switched in the circuit.

10. The receiver apparatus according to claim 4, wherein the hard-decision-based decoder unit and the soft-decision-based decoder unit are implemented as a single circuit, and wherein in accordance with whether the hard-decision-based decoder unit or the soft-decision-decoder unit is operated, the number of bits used in a decoding process is switched in the circuit.

11. A receiving method for decoding a received signal which is set at a variable transmission rate and which is coded, the decoding being performed such that, when the transmission rate for the received signal is of a threshold value or lower, the received signal is subject to hard decision before being decoded, and, when the transmission rate exceeds the threshold value, the received signal is subject to soft decision before being decoded.
